(19) United States
(12) Patent Application Publication
(10) Pub. No.: US 2025/0167823 A1
(43) Pub. Date: May 22, 2025

(54) METHODS OF MANUFACTURING A RADIO FREQUENCY FRONT END MODULE

(71) Applicant: Skyworks Solutions, Inc., Irvine, CA (US)

(72) Inventors: Manjunath Machnoor, Cedar Rapids, IA (US); Tao Wu, Marion, IA (US)

(21) Appl. No.: 18/917,861

(22) Filed: Oct. 16, 2024

Related U.S. Application Data
(60) Provisional application No. 63/600,520, filed on Nov. 17, 2023.
(60) Provisional application No. 63/609,194, filed on Dec. 12, 2023.

(51) Int. Cl. H04B 1/44; H03F 3/24; H04B 1/00

(52) U.S. Cl. CPC H04B 1/44; H03F 3/245; H04B 1/0057; H03F 2200/451

(57) ABSTRACT

A method of manufacturing a radio frequency front end module includes mounting a low-noise amplifier and a receive filter to a substrate in a receive path of the radio frequency front end module. The receive filter is connected between the low-noise amplifier and a first port configured for connection to an antenna. The method also includes mounting a power amplifier and a transmit filter to the substrate in a transmit path of the radio frequency front end module. In addition, the method includes forming an inductive coupled resonator connected between the transmit filter and the first port, the transmit filter connected between the inductive coupled resonator and the power amplifier.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field of the Invention

The present disclosure relates to front-end architectures for wireless applications.

### Description of the Related Art

In wireless applications, a signal to be transmitted is typically generated by a transceiver, amplified by a power amplifier, filtered by a filter, and routed to an antenna by a switch network. Such a signal transmitted through the antenna has a relatively high power.

In a generally reverse manner, a relatively weak signal received through an antenna is typically routed from the antenna by a switch network, filtered by a filter, amplified by a low-noise amplifier, and provided to the transceiver. In some applications, the amplification can be achieved in close proximity to the antenna to reduce loss of the relatively weak signal.

### SUMMARY

In some aspects, the techniques described herein relate to a method of manufacturing an inductive coupled resonator including: printing, on a first layer of a printed circuit board, a primary inductor coil; printing, on a second layer of the printed circuit board, a secondary inductor coil inductively coupled to the primary inductor coil; printing, on a third and a fourth layer of the printed circuit board, a pair of conductive plates to form a parallel plate capacitor; and connecting the parallel plate capacitor in series with the secondary inductor coil.

In some aspects, the techniques described herein relate to a method further including tuning the secondary inductor coil and the parallel plate capacitor to achieve resonance at a second harmonic frequency.

In some aspects, the techniques described herein relate to a method wherein tuning the secondary inductor coil includes forming an additional secondary inductor coil on any layer of the printed circuit board.

In some aspects, the techniques described herein relate to a method wherein tuning the secondary inductor coil includes connecting two or more of the secondary inductor coils in parallel.

In some aspects, the techniques described herein relate to a method of manufacturing a radio frequency front end module, the method including: mounting a low-noise amplifier and a receive filter to a substrate in a receive path of the radio frequency front end module, the receive filter connected between the low-noise amplifier and a first port configured for connection to an antenna; and mounting a power amplifier and a transmit filter to the substrate in a transmit path of the radio frequency front end module; and forming an inductive coupled resonator connected between the transmit filter and the first port, the transmit filter connected between the inductive coupled resonator and the power amplifier.

In some aspects, the techniques described herein relate to a method further wherein forming an inductive coupled resonator includes: printing, on a first layer of the substrate, a primary inductor coil; printing, on a second layer of the substrate, a secondary inductor coil inductively coupled to the primary inductor coil; printing, on a third and a fourth layer of the substrate, a pair of conductive plates to form a parallel plate capacitor; and connecting the parallel plate capacitor in series with the secondary inductor coil.

In some aspects, the techniques described herein relate to a method further including tuning the secondary inductor coil and the parallel plate capacitor to achieve resonance at a second harmonic frequency.

In some aspects, the techniques described herein relate to a method wherein tuning the secondary inductor coil includes forming an additional secondary inductor coil on any layer of the substrate.

In some aspects, the techniques described herein relate to a method wherein tuning the secondary inductor coil includes connecting two or more of the secondary inductor coils in parallel.

In some aspects, the techniques described herein relate to a method wherein the first port is a port of an antenna switch module.

In some aspects, the techniques described herein relate to a method further including mounting the antenna switch module to the substrate.

In some aspects, the techniques described herein relate to a method wherein the inductive coupled resonator includes a primary inductor coil connected between the transmit filter and the first port.

In some aspects, the techniques described herein relate to a method wherein the inductive coupled resonator further includes a secondary inductor coil inductively coupled to the primary inductor coil.

In some aspects, the techniques described herein relate to a method wherein the secondary inductor coil includes a plurality of inductively coupled parallel inductor coils.

In some aspects, the techniques described herein relate to a method wherein the primary inductor coil and the secondary inductor coil are each formed by a conductive stripline on a printed circuit board.

In some aspects, the techniques described herein relate to a method wherein the secondary inductor coil is connected in series with a capacitor.

In some aspects, the techniques described herein relate to a method wherein the capacitor is a parallel plate capacitor formed by a pair of conductive plates formed on separate layers of a printed circuit board.

In some aspects, the techniques described herein relate to a method wherein the substrate includes one or more printed circuit boards.

In some aspects, the techniques described herein relate to a radio frequency front-end module including: an antenna switch module; a receive path including a low-noise amplifier and a receive filter, the receive filter connected between a port of the antenna switch module and the low-noise amplifier; and a first transmit path including a power amplifier, a transmit filter, and an inductive coupled resonator, the inductive coupled resonator connected between the transmit filter and the port of the antenna switch module, the transmit filter connected between the inductive coupled resonator and the power amplifier.

In some aspects, the techniques described herein relate to a radio frequency front-end module wherein the inductive coupled resonator is configured to suppress second-order harmonics.

In some aspects, the techniques described herein relate to a radio frequency front-end module further including a second transmit path.

In some aspects, the techniques described herein relate to a radio frequency front-end module wherein the first transmit path is a mid-band transmit path and the second transmit path is a high-band transmit path.

In some aspects, the techniques described herein relate to a radio frequency front-end module wherein the first transmit path further includes a band switch connected to the transmit filter.

In some aspects, the techniques described herein relate to a radio frequency front-end module wherein the inductive coupled resonator includes a primary inductor coil connected between the transmit filter and the antenna switch module.

In some aspects, the techniques described herein relate to a radio frequency front-end module wherein the inductive coupled resonator further includes a secondary inductor coil inductively coupled to the primary inductor coil.

In some aspects, the techniques described herein relate to a radio frequency front-end module wherein the secondary inductor coil includes a plurality of inductively coupled parallel inductor coils.

In some aspects, the techniques described herein relate to a radio frequency front-end module wherein the primary inductor coil and the secondary inductor coil are each formed by a conductive stripline on a printed circuit board.

In some aspects, the techniques described herein relate to a radio frequency front-end module wherein the secondary inductor coil is connected in series with a capacitor.

In some aspects, the techniques described herein relate to a radio frequency front-end module wherein the capacitor is a parallel plate capacitor formed by a pair of conductive plates formed on separate layers of a printed circuit board.

In some aspects, the techniques described herein relate to a radio frequency front-end module wherein the transmit filter or the receive filter is a bulk acoustic wave or a surface acoustic wave filter.

In some aspects, the techniques described herein relate to a radio frequency front-end system including: a receive path including a low-noise amplifier and a receive filter, the receive filter connected between a first port configured for connection to an antenna and the low-noise amplifier; and a first transmit path including a power amplifier, a transmit filter, and an inductive coupled resonator, the inductive coupled resonator connected between the transmit filter and the first port, the transmit filter connected between the inductive coupled resonator and the power amplifier.

In some aspects, the techniques described herein relate to a radio frequency front-end system wherein the inductive coupled resonator is configured to suppress second-order harmonics.

In some aspects, the techniques described herein relate to a radio frequency front-end system further including a second transmit path.

In some aspects, the techniques described herein relate to a radio frequency front-end system wherein the first transmit path is a mid-band transmit path and the second transmit path is a high-band transmit path.

In some aspects, the techniques described herein relate to a radio frequency front-end system wherein the first transmit path further includes a band switch connected to the transmit filter.

In some aspects, the techniques described herein relate to a radio frequency front-end system wherein the inductive coupled resonator includes a primary inductor coil connected between the transmit filter and the first port.

In some aspects, the techniques described herein relate to a radio frequency front-end system wherein the inductive coupled resonator further includes a secondary inductor coil inductively coupled to the primary inductor coil.

In some aspects, the techniques described herein relate to a radio frequency front-end system wherein the secondary inductor coil includes a plurality of inductively coupled parallel inductor coils.

In some aspects, the techniques described herein relate to a radio frequency front-end system wherein the primary inductor coil and the secondary inductor coil are each formed by a conductive stripline on a printed circuit board.

In some aspects, the techniques described herein relate to a radio frequency front-end system wherein the secondary inductor coil is connected in series with a capacitor.

In some aspects, the techniques described herein relate to a radio frequency front-end system wherein the capacitor is a parallel plate capacitor formed by a pair of conductive plates formed on separate layers of a printed circuit board.

In some aspects, the techniques described herein relate to a radio frequency front-end system wherein the transmit filter or the receive filter is a bulk acoustic wave or a surface acoustic wave filter.

In some aspects, the techniques described herein relate to a mobile device including: a baseband system; a transceiver communicatively connected to the baseband system; a front-end module communicatively connected to the transceiver, the front-end module including an antenna switch module, a receive path including a low-noise amplifier and a receive filter, the receive filter connected between a port of the antenna switch module and the low-noise amplifier, and a first transmit path including a power amplifier, a transmit filter, and an inductive coupled resonator, the inductive coupled resonator coupled between the transmit filter and the port of the antenna switch module, the transmit filter connected between the inductive coupled resonator and the power amplifier; an antenna communicatively connected to the front-end module; and a power management system.

In some aspects, the techniques described herein relate to a mobile device wherein the inductive coupled resonator is configured to suppress second-order harmonics in the first transmit path.

In some aspects, the techniques described herein relate to a mobile device wherein the transmit filter or the receive filter is a bulk acoustic wave or a surface acoustic wave filter.

In some aspects, the techniques described herein relate to a mobile device wherein the first transmit path further includes a band switch connected to the transmit filter.

In some aspects, the techniques described herein relate to a mobile device wherein the inductive coupled resonator includes a secondary inductor coil inductively coupled to a primary inductor coil.

For purposes of summarizing the disclosure, certain aspects, advantages and novel features have been described herein. It is to be understood that not necessarily all such advantages may be achieved in accordance with any particular embodiment. Thus, the disclosed embodiments may be carried out in a manner that achieves or optimizes one advantage or group of advantages as taught herein without necessarily achieving other advantages as may be taught or suggested herein.

### BRIEF DESCRIPTION OF THE DRAWINGS

Throughout the drawings, reference numbers are re-used to indicate correspondence between referenced elements. The drawings are provided to illustrate embodiments of the inventive subject matter described herein and not to limit the scope thereof.

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3 is a schematic diagram of one embodiment of a mobile device.

FIG. 4 illustrates a front-end architecture having one or more features as described herein and configured to support multiple antennas.

FIG. 5 is a schematic diagram of one embodiment of a front-end module.

FIGS. 6A-6B are schematic diagrams of embodiments of a front-end module including an inductive coupled resonator.

FIG. 7A is a schematic diagram of one embodiment of an inductive coupled resonator.

FIG. 7B is a schematic diagram of another embodiment of the inductive coupled resonator.

FIG. 7C illustrates impedance matching by the inductive coupled resonator for the front-end module of FIG. 6A.

FIG. 8 is a schematic diagram of a front-end module having parallel transmit paths.

FIGS. 9A-9C are schematic diagrams of an embodiment of the inductive coupled resonator.

FIG. 9D is a schematic diagram of a printed circuit board layout including a capacitor plate of the inductive coupled resonator.

FIGS. 10A-10B illustrate impedance and capacitance for one embodiment of the inductive coupled resonator.

FIG. 11A illustrates a comparison of noise rejection for two embodiments of the front-end module.

FIG. 11B illustrates a comparison of voltage standing wave ratio for two embodiments of the front-end module.

FIG. 11C illustrates a comparison of in-band insertion loss for two embodiments of the front-end module.

FIGS. 11D-11E illustrate a comparison of second-order harmonics for two embodiments of the front end module.

FIG. 12A is a schematic diagram of one embodiment of a packaged module.

FIG. 12B is a schematic diagram of a cross-section of the packaged module of FIG. 12A taken along the lines 12B-12B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

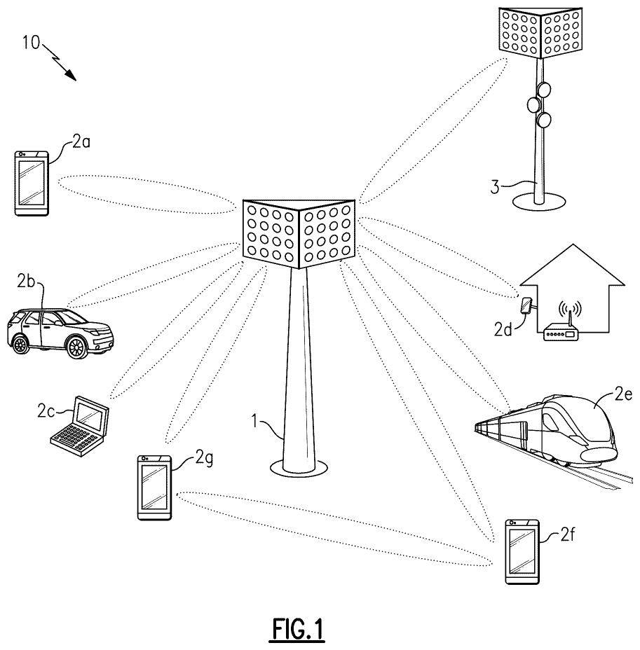

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1) in the range of about 410 MHz to about 7.125 GHZ, Frequency Range 2 (FR2) in the range of about 24.250 GHz to about 52.600 GHz, or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

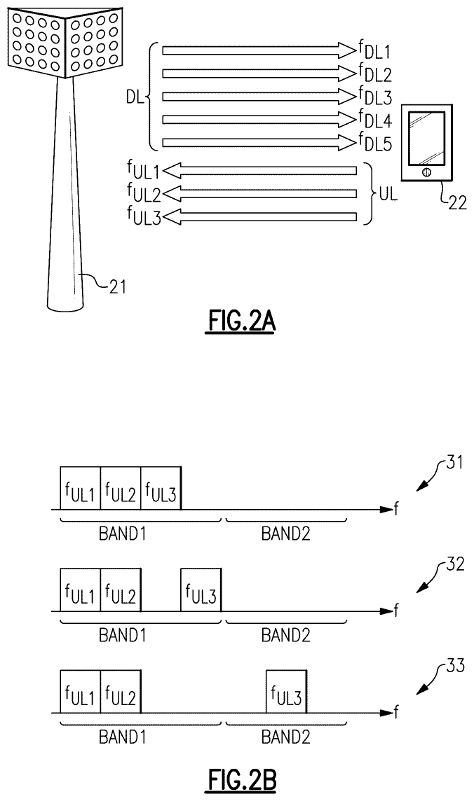

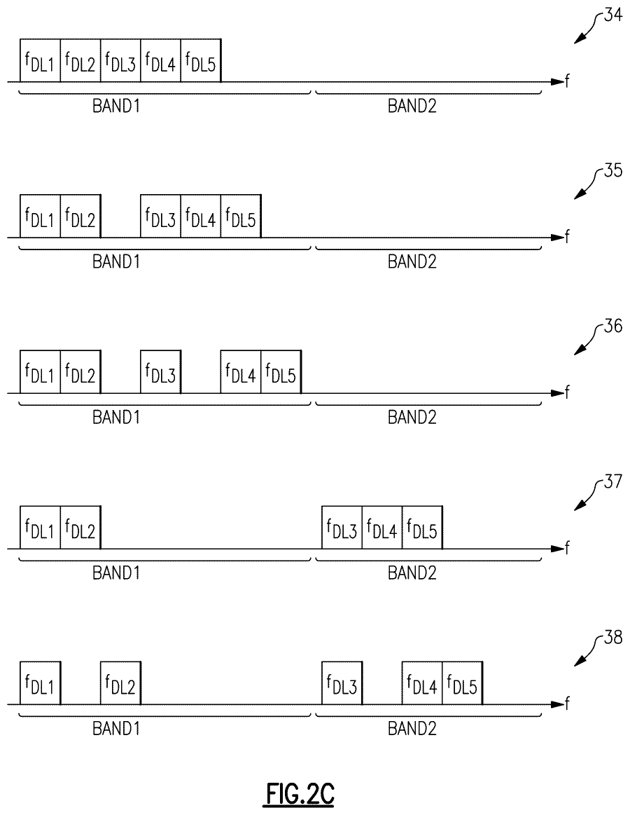

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink.

FIG. 3 is a schematic diagram of one embodiment of a mobile device 300. The mobile device 300 includes a baseband system 301, a transceiver 302, a front end system 303, antennas 304, a power management system 305, a memory 306, a user interface 307, and a battery 308.

The mobile device 300 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 302 generates RF signals for transmission and processes incoming RF signals received from the antennas 304. It will be understood that various functionalities associated with the transmission and receiving of RF signals can be achieved by one or more components that are collectively represented in FIG. 3 as the transceiver 302. In one example, separate components (for instance, separate circuits or dies) can be provided for handling certain types of RF signals.

The front end system 303 aids in conditioning signals transmitted to and/or received from the antennas 304. In the illustrated embodiment, the front end system 303 includes antenna tuning circuitry 310, power amplifiers (PAS) 311, low noise amplifiers (LNAs) 312, filters 313, switches 314, and signal splitting/combining circuitry 315. However, other implementations are possible.

For example, the front end system 303 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 300 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 304 can include antennas used for a wide variety of types of communications. For example, the antennas 304 can include antennas for transmitting and/or receiving signals associated with a wide variety of frequencies and communications standards.

In certain implementations, the antennas 304 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 300 can operate with beamforming in certain implementations. For example, the front end system 303 can include amplifiers having controllable gain and phase shifters having controllable phase to provide beam formation and directivity for transmission and/or reception of signals using the antennas 304. For example, in the context of signal transmission, the amplitude and phases of the transmit signals provided to the antennas 304 are controlled such that radiated signals from the antennas 304 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 304 from a particular direction. In certain implementations, the antennas 304 include one or more arrays of antenna elements to enhance beamforming.

The baseband system 301 is coupled to the user interface 307 to facilitate processing of various user input and output (I/O), such as voice and data. The baseband system 301 provides the transceiver 302 with digital representations of transmit signals, which the transceiver 302 processes to generate RF signals for transmission. The baseband system 301 also processes digital representations of received signals provided by the transceiver 302. As shown in FIG. 3, the baseband system 301 is coupled to the memory 306 of facilitate operation of the mobile device 300.

The memory 306 can be used for a wide variety of purposes, such as storing data and/or instructions to facilitate the operation of the mobile device 300 and/or to provide storage of user information.

The power management system 305 provides a number of power management functions of the mobile device 300. In certain implementations, the power management system 305 includes a PA supply control circuit that controls the supply voltages of the power amplifiers 311. For example, the power management system 305 can be configured to change the supply voltage(s) provided to one or more of the power amplifiers 311 to improve efficiency, such as power added efficiency (PAE).

As shown in FIG. 3, the power management system 305 receives a battery voltage from the battery 308. The battery 308 can be any suitable battery for use in the mobile device 300, including, for example, a lithium-ion battery.

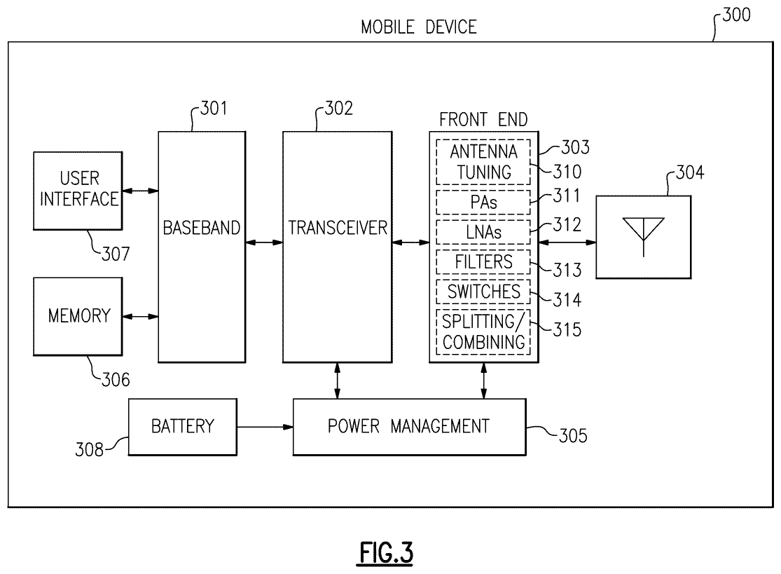

FIG. 4 depicts a front-end architecture 400 having one or more features as described herein, and configured to support multiple antennas. More particularly, the front-end architecture 400 is shown to be coupled to four antennas 401, 402, 403, 404. Each of such antennas can facilitate transmit (TX) and/or receive (RX) operations through the front-end architecture 400.

For transmit operations, the front-end architecture 400 can be in communication with, for example, a transceiver to receive, process, and route one or more transmit signals to one or more of the antennas 401, 402, 403, 404. The one or more transmit signals are collectively depicted as an arrow 407.

For transmit operations, the front-end architecture 400 can receive one or more signals from one or more of the antennas 401, 402, 403, 404, process such signal(s), and route such processed signal(s) to, for example, a transceiver which may or may not be the same as the foregoing transceiver associated with the transmit operations. The one or more received signals are collectively depicted as an arrow 408.

The front-end architecture 400 can also include a carrier aggregation (CA) functionality provided by one or more modules collectively referred to as carrier aggregation architecture 409 a. Such a carrier aggregation functionality can include an uplink (UL) carrier aggregation (UL CA) functionality and/or a downlink (DL) carrier aggregation (DL CA) functionality. For the purpose of description, it will be understood that in a given CA functionality, a plurality of signals associated with the CA functionality may or may not share a common antenna or a common signal path. The front-end architecture 400 can also include a multiple input multiple output (MIMO) functionality provided by one or more modules collectively referred to as MIMO architecture 409 b.

For the purpose of description, the following assumptions can be made. First, a given platform solution can be assumed to support full hot-swapping that enables a front-end architecture to be desirably configured for connectivity and active path selection. For example, primary component carrier(s) (PCC) can be supported by an uplink carrier aggregation (UL CA) module or component, and secondary component carrier(s) (SCC) can be supported by a primary module or component, or vice versa. In another example, transmit (TX) and receive (RX) operations do not necessarily need to share the same path (e.g., TX can be from an UL CA module, RX can be from the UL CA module, primary module, or a secondary RX module).

Second, four antennas are assumed to be available with the following defined band support listed in Table 1.

TABLE 1

| Antenna | Band support |
|---|---|
| Ant. 1 | MB/HB/UHB/eLAA |
| Ant. 2 | LB/MB/MLB/HB/UHB/eLAA |
| Ant. 3 | MB/HB/UHB/eLAA |
| Ant. 4 | LB/MB/MLB/HB/UHB/eLAA |

Table 2 lists examples of frequency ranges referenced in Table 1. It will be understood that one or more features of the present disclosure can also be implemented with other frequency ranges of the various example bands.

TABLE 2

| Band | Example frequency range | |
|---|---|---|
| LB (low-band) | 698-960 | MHz |
| MLB (mid-low-band) | 1427-1518 | MHz |
| MB (mid-band) | 1710-2200 | MHz |
| HB (high-band) | 2300-2690 | MHz |
| UHB (ultra-high-band) | 3400-3800 | MHz |
| eLAA (enhanced LAA) | 5150-5925 | MHz |

For the purpose of description, low, mid and high bands are referred to herein as LB, MB and HB, or simply as L, M and H, respectively. The latter set of abbreviations are utilized herein for combinations of bands. For example, LM refers to a combination of LB and MB, LMH refers to a combination of LB, MB and HB, MM refers to a combination of MB and MB, etc.

In some embodiments, a front-end architecture or system having one or more features as described herein can include some or all of the following. First, in some embodiments, a system can be configured for simultaneous operations of LM UL CA and 4×4 MB MIMO; simultaneous operations of LM UL CA and 4×4 HB MIMO; simultaneous operations of LH UL CA and 4×4 MB MIMO; simultaneous operations of LH UL CA and 4×4 HB MIMO; simultaneous operations of MM UL CA and 4×4 MB MIMO; simultaneous operations of MM UL CA and 4×4 HB MIMO; simultaneous operations of MH UL CA and 4×4 MB MIMO; simultaneous operations of MH UL CA and 4×4 HB MIMO; simultaneous operations of HH UL CA and 4×4 MB MIMO; and simultaneous operations of HH UL CA and 4×4 HB MIMO.

Second, in some embodiments, a single module can be configured to flexibly support all possible or targeted UL CA operations.

Third, in some embodiments, flexible support of 4×4 and higher order MIMO for bands greater than 1710 MHz can be implemented.

Fourth, in some embodiments, support end-to-end user equipment (UE) antenna swap and/or antenna switch diversity for at least one antenna.

Fifth, in some embodiments, duplication of filtering/RX paths can be minimized or reduced for smallest or reduced size and/or cost. In such a configuration, TX-only filtering in an UL CA module (e.g., as opposed to full duplexers and/or quadplexers) can be implemented. Also, lower cost and/or smaller size UL CA solutions can be realized, as well as considerable reductions in TX insertion loss (IL) for UL CA path(s).

Sixth, in some embodiments, insertion loss across all targeted band support and CA support configurations can be reduced or minimized.

Seventh, in some embodiments, maximal or increased use of antenna isolation for enhanced performance in CA combinations can be realized.

In some embodiments, one or more features of the present disclosure can be implemented in various connectivity configurations. Eight non-limiting examples are described herein.

In addition, aspects of the various connectivity configurations are implemented in example architecture embodiments that are described herein. Some architectural embodiments include MB and HB MIMO DRx modules employing MB/HB switch-combined filters. Various architectural embodiments include MB and HB MIMO DRx not employing MB/HB switch combining. Certain architectural embodiments leverage MB/MB switch-combining in the MB/HB MIMO DRx module. Variations on these architectural embodiments can include, for example and without limitation, placement of LB duplexing after an antenna switch (e.g., a mPnT switch) for advantages in harmonic margin of the harmonically related CA cases, at a slight penalty in insertion loss for that specific antenna path.

In some embodiments, advanced phones required to support 4×4 DL MIMO (multiple-input multiple-output) can include four antennas. One or more features of the present disclosure can be configured to optimize or enhance connectivity to these available antennas. Some designs can include a multi-throw high isolation/high linearity switch for antenna selection. Front-end architectures disclosed herein can establish enhanced or optimal diplexing or triplexing of signal paths to support all targeted UL CA and MIMO use cases. These architectures can also bypass the diplexer and/or triplexer to reduce insertion loss in single band operation.

In some embodiments, front-end architectures disclosed herein can be implemented to establish reduced or minimal TX filtering in the MB/HB MIMO DRx module for reduced cost and/or smaller size. Such architectures can be configured to leverage the re-use of existing TX filters, duplex filters, switch-combined filters, and/or ganged filters in the MB and HB primary PAID, thereby reducing or minimizing filter duplication of the overall architecture.

In some embodiments, front-end architectures disclosed herein can be configured to support 1) using MB/HB switch-combined filter implementations in the MB/HB MIMO DRx module, or 2) no MB/HB switch-combined filter implementations in the MB/HB MIMO DRx module. Such architectures can be configured to employ MB/MB switch-combining in the MB/HB MIMO DRx module.

In some embodiments, front-end architectures disclosed herein can be configured to enable LB diplexing before or after a mPnT switch. This can enhance or optimize trade-offs between harmonic margin in harmonically related CA and insertion loss for the signal paths supported by the LB antenna.

In some embodiments, front-end architectures disclosed herein can be configured to support LB antenna swapping and harmonic filtering for harmonically-related CA performance with a diplexer following an antenna swap switch. In such embodiments, both sides of the diplexer can be flexibly connected to poles of that antenna swap switch.

In some embodiments, front-end architectures disclosed herein can be configured to integrate TX filtering that can be ganged with RX filtering or TX filtering that can be switch-combined with RX filtering that is implemented in the MB/HB MIMO DRx module. In such embodiments, the UL CA power amplifier module and the MIMO DRx module can be separate modules.

In some embodiments, front-end architectures disclosed herein can be configured to integrate the UL CA power amplifier with the TX filtering and RX filtering of the MB/HB MIMO DRx module using a single module (e.g., a UL CA PAM+MIMO DRx module).

### Inductive Coupled Resonator

FIG. 5 is a schematic diagram of one embodiment of a front-end module 500 implementing a parallel inductor-capacitor (LC) trap 510. The front-end module 500 generally includes a transmit path and a receive path connected to an antenna by an antenna switch module (ASM). Those skilled in the art will appreciate that the parallel inductor and capacitor of the LC trap 510 have a resonant frequency which can be tuned to selectively pass a narrow TX band of the front-end module 500. However, the parallel LC trap 510 can affect the input impedance of the front-end module, increasing losses across multiple bands by creating an impedance mismatch and changing the fundamental frequency (f0) of the circuit.

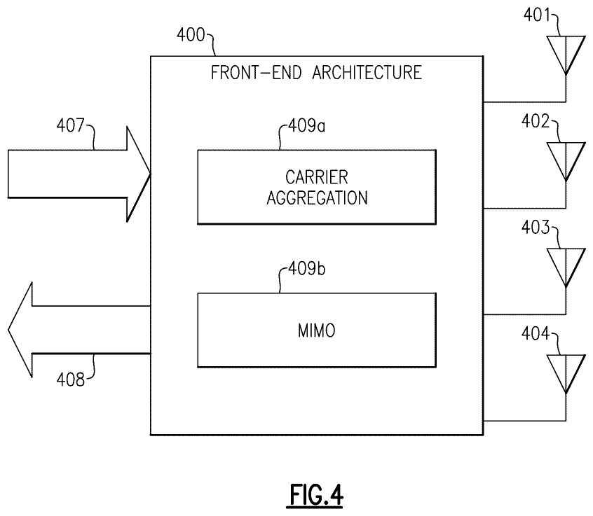

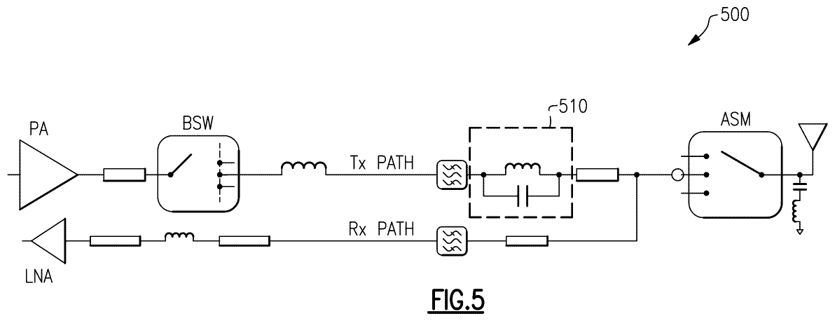

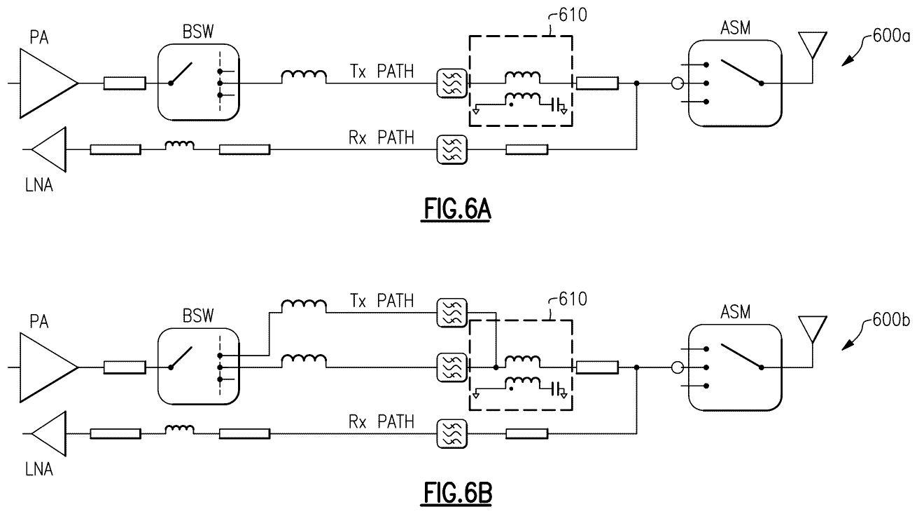

FIG. 6A and FIG. 6B are schematic diagrams of two embodiments of a front-end module 600a/b implementing an inductive coupled resonator 610. Each front-end module 600a/b has at least one transmit path connecting a power amplifier (PA) to the antenna via the ASM, and a receive path connecting the antenna to a low-noise amplifier (LNA). In certain embodiments (i.e., the front-end module 600b), two or more parallel TX paths can each include signal conditioning and/or filtering stages for a corresponding frequency band. The TX path(s) can further include a band switch (BSW) to selectively connect one of the signal conditioning and/or filtering stages to the PA. The inductive coupled resonator 610 improve rejection of second-order harmonics (2f0) in the transmit path before they reach the antenna, while avoiding losses and impedance mismatch associated with the parallel LC trap 510.

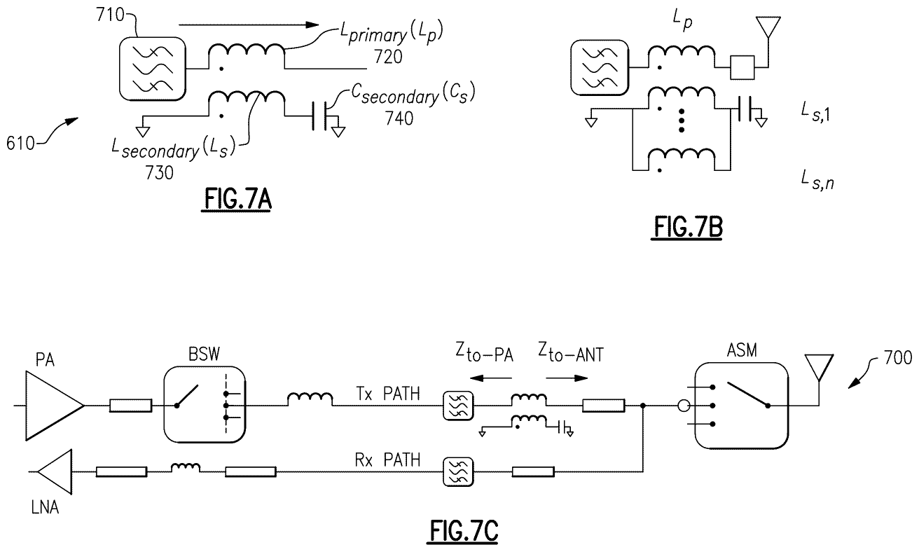

Referring now to FIGS. 7A-7C, an example of impedance matching 700 by the inductive coupled resonator 610 is schematically illustrated. In one embodiment, the inductive coupled resonator 610 includes a primary inductor 720 (Lₚ) connected to a filter 710 in the TX path of a front-end module. In certain embodiments, the TX path filter 710 and/or an RX path filter can be acoustic wave filters, such as bulk acoustic wave (BAW) or surface acoustic wave (SAW) filters. A secondary inductor 730 (Lₛ) and a secondary capacitor 740 (Cₛ) are grounded adjacent to the primary inductor 720, with the inductors being inductively coupled such that second-order harmonics in the TX path (e.g., harmonics generated by the filter 710) are coupled to the circuit ground. Inductance and capacitance of the secondary inductor 730 and the secondary capacitor 740 can be tuned to suppress harmonics or other undesired frequencies without affecting the in-band fundamental frequency of the TX path. For example, reflected impedance on the primary inductor 720 due to coupled inductor 730 and capacitor 740 is given by:

$${Z}_{reflected - Primary} ( ω ) = \frac{{w}^{2} {K}_{12}^{2} {L}_{S} {L}_{p}}{j ω {L}_{s} + {R}_{L s} + \frac{1}{j ω {C}_{s}}}$$

$${Z}_{reflected - Primary} ( {ω}_{r} ) = \frac{{w}^{2} {K}_{12}^{2} {L}_{S} {L}_{p}}{{R}_{L s}}$$

where ω is the operating frequency of the TX path and ωᵣ is the resonant frequency of the secondary inductor 730 and the secondary capacitor 740, K₁₂ is the coupling co-efficient between 720 (Lₚ) and 730 (Lₛ).

In certain embodiments, the inductive coupled resonator 610 can further include additional secondary inductors 730 connected in parallel to the secondary capacitor 740. The inductance and number of secondary inductors 730 may be selected depending on the application to tune the front-end module for better rejection of harmonics. A first secondary inductor (designated L_{s,1}) is inductively coupled to the primary inductor 720 (Lₚ), while a second secondary inductor (designated L_{s,2}) is inductively coupled to the first secondary inductor (L_{s,1}). For n parallel secondary inductors 730, each pair of adjacent inductors are coupled in this manner up to a last secondary inductor (designated L_{s,n}) and a second to last secondary inductor (designated L_{s,n-1}).

The location of the inductive coupled resonator 610 in the TX path can be selected to balance reflected power from the power amplifier (Z_{to-PA}) and the antenna (Z_{to-ANT}). For example, FIG. 7C illustrates a setup for the front-end module 600a to maximize the amount of harmonic power coupled by the pair of inductors 610, wherein Z_{to-ANT}=conjugate (Z_{to-PA}). Ideally, resistance in the TX path should be minimized, and Z_{reflected} is purely real. The amount of harmonic power delivered to the secondary coil of the coupled inductors 610 is given by:

$${Z}_{reflected} {I}_{primary}^{2} = {Z}_{reflected} \frac{{V}_{2 f 0}^{2}}{{( {Z}_{to - ANT} + {Z}_{to - PA} + {Z}_{reflected} )}^{⋀} 2}$$

FIG. 8 is a schematic diagram of another embodiment of a front-end module 800 having parallel transmit paths supporting mid-band (MB) and high-band (HB) TX. In this example, each frequency band (B1, B3, B41, B66, B201) can have its own transmit path with one or more corresponding filtering and conditioning stages. The inductive coupled resonator 610 is provided in the transmit path for band B3 (designated B3TX) to improve noise rejection in the receive path (B7RX). Additionally, or alternatively, another inductive coupled resonator 610 may be provided in the transmit paths for either of band B1 (B1TX) or band B41 (B41TX).

Each inductive coupled resonator 610 can be tuned to specifically target second-order harmonic frequencies of the corresponding TX path. For certain TX bands, second and third-order harmonic frequencies may not overlap with any RX band of the front-end module 800. In that case, the inductive coupled resonator 610 may be reserved for those TX paths for which rejection of the harmonics is particularly useful to improve RX performance of the FEM 800.

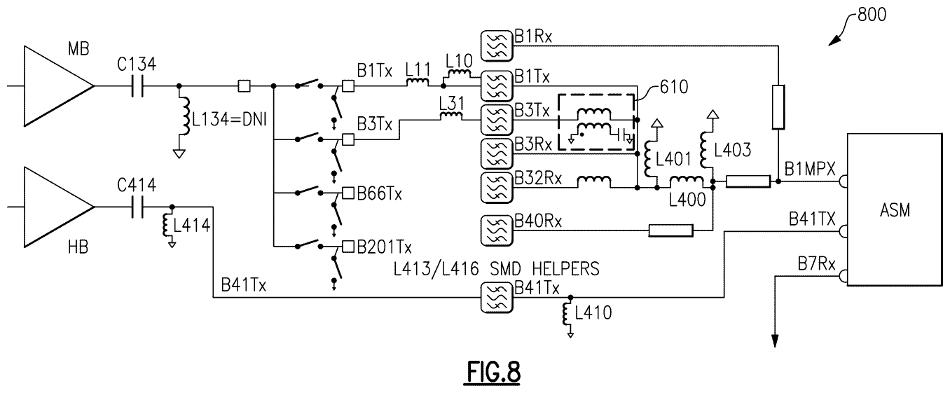

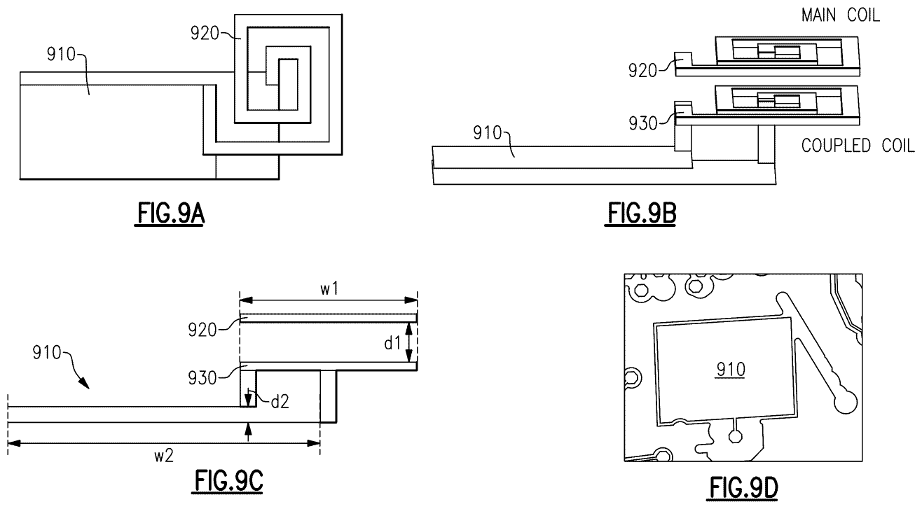

FIGS. 9A-9C are layout diagrams of one embodiment of the inductive coupled resonator 610. FIG. 9A is a top plan view illustrating a parallel plate capacitor 910 (i.e., the secondary capacitor 740), and a main coil 920 which forms the primary inductor 720. FIG. 7B is a perspective view further illustrating a coupled coil 930 which forms the secondary inductor 730. The main coil 920 and the coupled coil 930 may each be formed as a microstrip on a printed circuit board (PCB), or by any other method known to those skilled in the art. Each end of the coupled coil 930 is connected to a corresponding plate of the parallel plate capacitor 910 by a projection (“leg”) extending from a corner of the plate. In certain embodiments, the projections may connect to the coupled coil 930 elsewhere on the plates. Although the main coil 920 and the coupled coil 930 are each shown to have a substantially square profile, the coils can also have an elongated (i.e., rectangular or oblong and/or circular) profile to accommodate the layout of a multi-chip module (MCM).

FIG. 9C is an elevational view of the inductive coupled resonator 610 illustrating a width (w1) and a distance (d1) between the main coil 920 and the coupled coil 930. For embodiments wherein the main coil 920 and the coupled coil 930 are both formed within a PCB, the distance d1 can be a distance between respective layers of the PCB. The width w1 of the main coil 920 and the coupled coil 930 are not necessarily the same, but coils sharing a same profile and separated by a smaller distance d1 will generally provide better inductive coupling. In one example, the width w1 can be in a range of 5 mm to 10 mm and the distance d1 can be in a range of 0.1 mm to 1.6 mm.

FIG. 9C further illustrates a width (w2) and a distance (d2) between either plate of the parallel plate capacitor 910. It will be appreciated that a lower one of the capacitor plates can have a substantially larger footprint (and width w2) than an upper one of the capacitor plates. Those skilled in the art will envision how the footprint of each capacitor plate and the distance d2 can be adjusted to match a desired capacitance value for tuning the inductive coupled resonator 610. In one example, the width w1 can be in a range of 1 mm to 40 mm and the distance d1 can be in a range of 0.1 mm to 1.6 mm.

FIG. 9D is a schematic diagram of one layer of a printed circuit board, illustrating a first plate of the parallel plate capacitor 910. The first plate is formed of a conductive material (such as copper, gold, aluminum, etc.) deposited on or between a dielectric substrate of the PCB. A conductive trace projecting from an edge or corner of the first plate can provide a surface to connect to a corresponding leg of the coupled coil 930 without substantially affecting the capacitance of the capacitor 910.

A method of manufacturing an inductive coupled resonator according to any of the previous figures includes printing, on a first layer of the PCB, the main inductor coil 920 in series with the antenna switch module (ASM) and one or more filters. The method further includes printing, on a second layer of the PCB, the coupled inductor coil 930 configured to resonate with the parallel plate capacitor 910 printed on a third and fourth layer of the PCB. The coupled inductor coil 930 is tuned until mutual inductance is sufficient such that in-band performance in the TX path is substantially unaffected by the inductive coupled resonator 610. Then, the parallel plate capacitor 910 is tuned to achieve resonance at the second harmonic frequency of the TX band. Additional coupled coils 930 can be added in parallel, and the coils and capacitor tuned as needed until desired performance in the TX band is achieved.

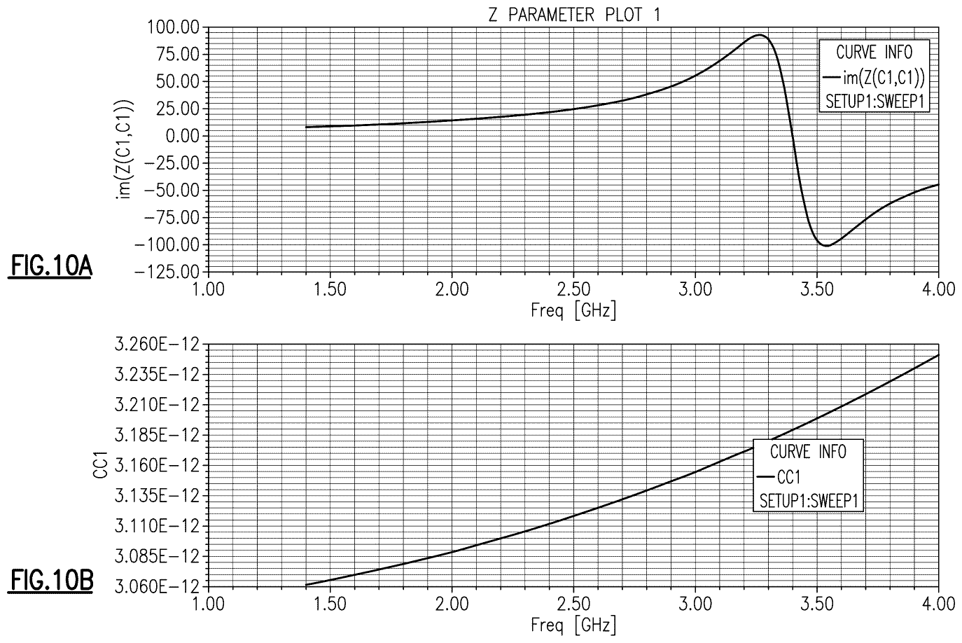

FIGS. 10A-10B illustrate impedance and capacitance for a simulated embodiment of the inductive coupled resonator 610. As discussed above, the resonant frequency of the inductive coupled resonator 610 is tuned based on the inductance and capacitance values of the circuit elements to achieve coupling of second-order harmonics in the TX path. In this example, the parallel plate capacitor 910 has a simulated capacitance of 3.14 pF and the secondary inductor has a simulated inductance of 0.8 nH. The desired resonant frequency of the circuit is 3.4 GHz, which is at the lower end of second-order harmonics in the B3 band. FIG. 10A shows a zero-crossing at 3.4 GHz, indicating that impedance is zero at the resonant frequency, and FIG. 10B shows that capacitance of the circuit is approximately 3.15 pF at the resonant frequency. Accordingly, the inductive coupled resonator 610 will couple second-order harmonics to the circuit ground without substantially changing the impedance or in-band TX performance of a front-end module.

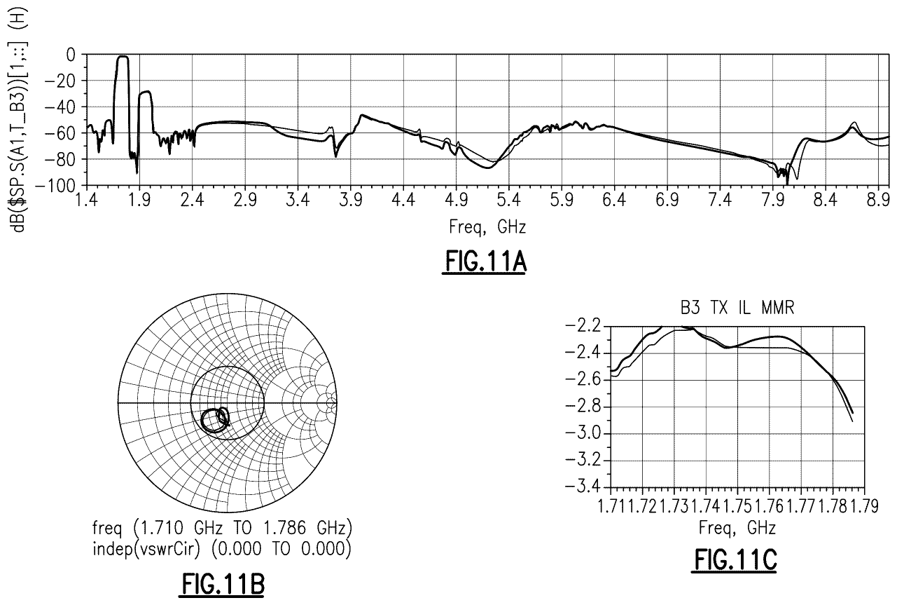

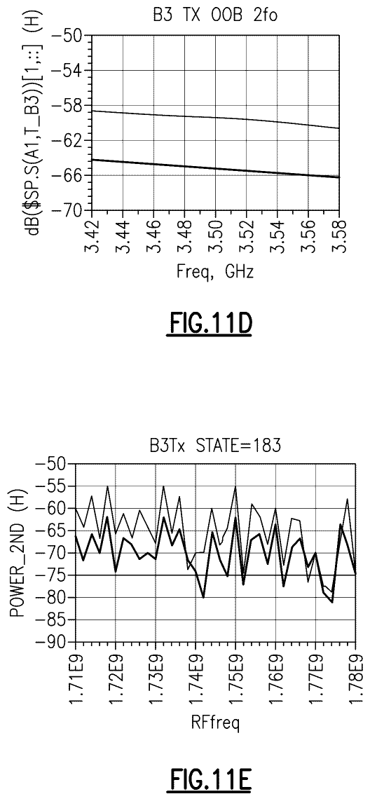

FIGS. 11A-11E illustrate a comparison of various performance characteristics for a baseline front-end module and a front-end module including the inductive coupled resonator 610. It will be seen that the inductive coupled resonator 610 generally improves performance of the front-end at certain frequencies without negatively affecting the performance in other aspects.

FIG. 11A illustrates noise rejection for both embodiments of the front-end module. Below 3 GHz, very little difference is visible in the amount of noise. However, at other frequencies associated with second-order harmonics (particularly 3.7-3.8 GHz, 4.5-5.3 GHz, and 8 GHZ), the noise level is reduced by up to 7 dB for the front-end module including the inductive coupled resonator 610.

FIG. 11B is a Smith chart illustrating voltage standing wave ratio (VSWR) for both embodiments of the front-end module. No difference is visible, indicating that in-band impedance of the TX path is substantially unchanged.

FIG. 11C illustrates in-band insertion loss for both embodiments of the front-end module. With the inductive coupled resonator 610 present, insertion loss is generally improved from 1.71-1.73 GHz and 1.75-1.77 GHz.

FIGS. 11D-11E illustrate a comparison of second-order harmonics for both embodiments of the front end module. With the inductive coupled resonator 610 present, the power of the harmonics is generally reduced by up to 7 dB as in FIG. 11A.

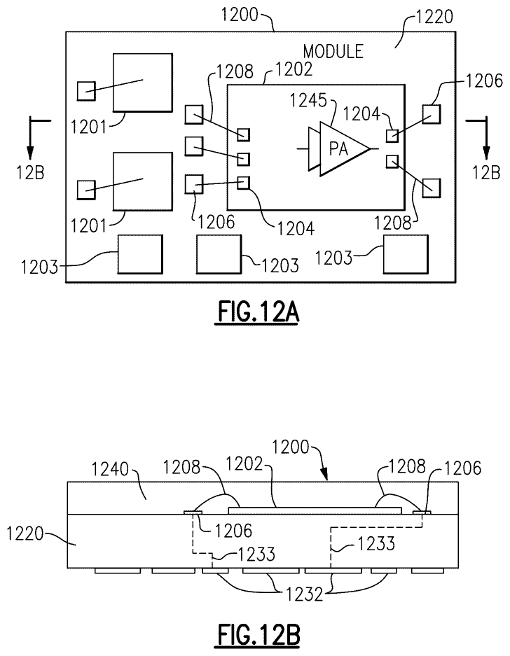

FIG. 12A is a schematic diagram of one embodiment of a packaged module 1200 which can include the front-end module and the inductive coupled resonator of any of the previous figures. FIG. 12B is a schematic diagram of a cross-section of the packaged module 1200 of FIG. 12A taken along the lines 12B-12B.

The packaged module 1200 includes radio frequency components 1201, a semiconductor die 1202, surface mount devices 1203, wirebonds 1208, a package substrate 1220, and an encapsulation structure 1240. The package substrate 1220 includes pads 1206 formed from conductors disposed therein. Additionally, the semiconductor die 1202 includes pins or pads 1204, and the wirebonds 1208 have been used to connect the pads 1204 of the die 1202 to the pads 1206 of the package substrate 1220.

The semiconductor die 1202 includes a power amplifier 1245, which can be implemented in accordance with one or more features disclosed herein.

The packaging substrate 1220 can be configured to receive a plurality of components such as radio frequency components 1201, the semiconductor die 1202 and the surface mount devices 1203, which can include, for example, surface mount capacitors and/or inductors. In one implementation, the radio frequency components 1201 include integrated passive devices (IPDs).

As shown in FIG. 12B, the packaged module 1200 is shown to include a plurality of contact pads 1232 disposed on the side of the packaged module 1200 opposite the side used to mount the semiconductor die 1202. Configuring the packaged module 1200 in this manner can aid in connecting the packaged module 1200 to a circuit board, such as a phone board of a mobile device. The example contact pads 1232 can be configured to provide radio frequency signals, bias signals, and/or power (for example, a power supply voltage and ground) to the semiconductor die 1202 and/or other components. As shown in FIG. 12B, the electrical connections between the contact pads 1232 and the semiconductor die 1202 can be facilitated by connections 1233 through the package substrate 1220. The connections 1233 can represent electrical paths formed through the package substrate 1220, such as connections associated with vias and conductors of a multilayer laminated package substrate.

In some embodiments, the packaged module 1200 can also include one or more packaging structures to, for example, provide protection and/or facilitate handling. Such a packaging structure can include overmold or encapsulation structure 1240 formed over the packaging substrate 1220 and the components and die(s) disposed thereon.

It will be understood that although the packaged module 1200 is described in the context of electrical connections based on wirebonds, one or more features of the present disclosure can also be implemented in other packaging configurations, including, for example, flip-chip configurations.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece or smart eyeglasses or virtual reality equipment, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, IoT radios, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly coupled, or coupled by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A method of manufacturing a radio frequency front end module, the method comprising:
mounting a low-noise amplifier and a receive filter to a substrate in a receive path of the radio frequency front end module, the receive filter connected between the low-noise amplifier and a first port configured for connection to an antenna; and
mounting a power amplifier and a transmit filter to the substrate in a transmit path of the radio frequency front end module; and
forming an inductive coupled resonator connected between the transmit filter and the first port, the transmit filter connected between the inductive coupled resonator and the power amplifier.

2. The method of claim 1 further wherein forming an inductive coupled resonator includes:
printing, on a first layer of the substrate, a primary inductor coil; and
printing, on a second layer of the substrate, a secondary inductor coil inductively coupled to the primary inductor coil;

3. The method of claim 2 wherein forming an inductive coupled resonator further includes:
printing, on a third and a fourth layer of the substrate, a pair of conductive plates to form a parallel plate capacitor; and
connecting the parallel plate capacitor in series with the secondary inductor coil.

4. The method of claim 3 further comprising tuning the secondary inductor coil and the parallel plate capacitor to achieve resonance at a second harmonic frequency.

5. The method of claim 4 wherein tuning the secondary inductor coil includes forming an additional secondary inductor coil on any layer of the substrate.

6. The method of claim 5 wherein tuning the secondary inductor coil includes connecting two or more of the secondary inductor coils in parallel.

7. The method of claim 1 wherein the first port is a port of an antenna switch module.

8. The method of claim 7 further comprising mounting the antenna switch module to the substrate.

9. The method of claim 1 wherein the inductive coupled resonator includes a primary inductor coil connected between the transmit filter and the first port.

10. The method of claim 9 wherein the inductive coupled resonator further includes a secondary inductor coil inductively coupled to the primary inductor coil.

11. The method of claim 10 wherein the secondary inductor coil includes a plurality of inductively coupled parallel inductor coils.

12. The method of claim 10 wherein the primary inductor coil and the secondary inductor coil are each formed by a conductive stripline on a printed circuit board.

13. The method of claim 10 wherein the secondary inductor coil is connected in series with a capacitor.

14. The method of claim 13 wherein the capacitor is a parallel plate capacitor

15. The method of claim 14 wherein the parallel plate capacitor includes a pair of conductive plates formed on separate layers of a printed circuit board.

16. The method of claim 1 wherein the substrate includes one or more printed circuit boards.

17. A method of manufacturing an inductive coupled resonator comprising:
printing, on a first layer of a printed circuit board, a primary inductor coil;
printing, on a second layer of the printed circuit board, a secondary inductor coil inductively coupled to the primary inductor coil;
printing, on a third and a fourth layer of the printed circuit board, a pair of conductive plates to form a parallel plate capacitor; and
connecting the parallel plate capacitor in series with the secondary inductor coil.

18. The method of claim 17 further comprising tuning the secondary inductor coil and the parallel plate capacitor to achieve resonance at a second harmonic frequency.

19. The method of claim 18 wherein tuning the secondary inductor coil includes forming an additional secondary inductor coil on any layer of the printed circuit board.

20. The method of claim 19 wherein tuning the secondary inductor coil includes connecting two or more of the secondary inductor coils in parallel.
